(19) United States
(12) Patent Application Publication
(10) Pub. No.: US 2026/0157206 A1
(43) Pub. Date: Jun. 4, 2026

(54) SEMICONDUCTOR DEVICE AND METHOD FORMING THEREOF

(71) Applicant: PowerX Semiconductor Corporation, Hsinchu County (TW)

(72) Inventor: Wei Lin CHEN, Hsinchu County (TW)

(21) Appl. No.: 19/097,884

(22) Filed: Apr. 2, 2025

(30) Foreign Application Priority Data
Dec. 4, 2024 (TW) 113147067

(51) Int. Cl. H01L 23/498; H01L 21/768

(52) U.S. Cl. CPC H10W 70/685; H10W 20/043; H10W 20/048

(57) ABSTRACT

A method of forming a semiconductor device includes forming a first seed layer over a dielectric layer; forming a second seed layer over the first seed layer; forming a routing layer over the second seed layer; etching the second seed layer by using the routing layer as a first mask; etching the first seed layer by using the second seed layer as a second mask; after etching the first seed layer, etching the routing layer and the second seed layer, in which after etching the routing layer and the second seed layer, an undercut is formed between the first seed layer and the second seed layer.

### CROSS-REFERENCE TO RELATED APPLICATION

This application claims priority to Taiwan Application Serial Number 113147067, filed Dec. 4, 2024, which is herein incorporated by reference in its entirety.

### BACKGROUND

### Field of Invention

The present disclosure relates to a semiconductor device and method forming thereof.

### Description of Related Art

In semiconductor processes, a redistribution layer (RDL) is used to add additional metal layers over the surface of a chip or wafer to redistribute and optimize the circuit interconnect layout. In modern semiconductor industries, wires in the redistribution layer are formed thinner to accommodate enough interconnects in smaller chips. However, when the wires are made thinner, it can lead to additional issues, potentially resulting in poor wire yield.

### SUMMARY

Some embodiments of the present disclosure provide a method of forming a semiconductor device including forming a first seed layer over a dielectric layer; forming a second seed layer over the first seed layer; forming a routing layer over the second seed layer; etching the second seed layer by using the routing layer as a first mask; etching the first seed layer by using the second seed layer as a second mask; after etching the first seed layer, etching the routing layer and the second seed layer, in which after etching the routing layer and the second seed layer, an undercut is formed between the first seed layer and the second seed layer.

Some embodiments of the present disclosure provides a semiconductor device including a conductive pad, a dielectric layer, and a routing structure. The dielectric layer is over the conductive pad. The routing structure penetrates the dielectric layer and is electrically connected with the conductive pad. The routing structure includes a first seed layer, a second seed layer, and a routing layer. The first seed layer is over the dielectric layer. The second seed layer is over the first seed layer, in which a width of a top portion of the second seed layer is substantially the same as a width of the first seed layer, and a first undercut is between the first seed layer and the second seed layer. The routing layer is over the second seed layer.

### BRIEF DESCRIPTION OF THE DRAWINGS

FIGS. 1-9 illustrate cross-section views of forming a semiconductor device in some embodiments of the present disclosure.

FIG. 10 illustrates an enlargement view of region M in FIG. 9.

### DETAILED DESCRIPTION

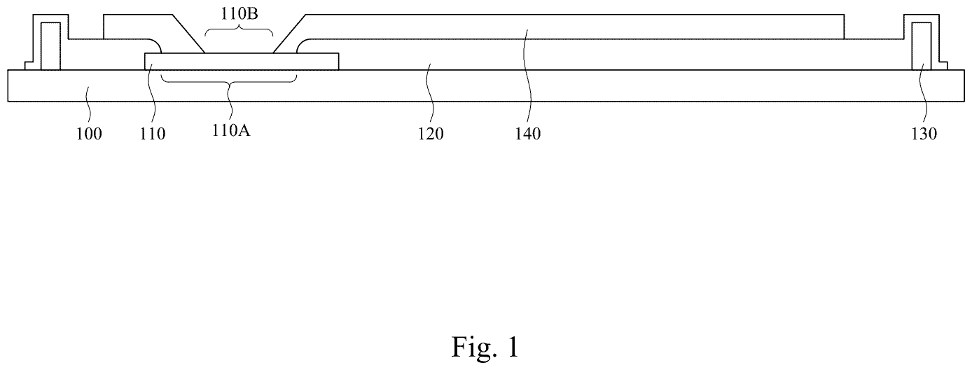

FIGS. 1-9 illustrate cross-section views of forming a semiconductor device in some embodiments of the present disclosure. Referring to FIG. 1, a conductive pad 110, a passivation layer 120, and a seal ring 130 are formed over a substrate 100. The passivation layer 120 is formed over the conductive pad 110 and the seal ring 130, and exposes a first portion 110A of the conductive pad 110. The seal ring 130 surrounds the semiconductor device. In some embodiments, the substrate 100 can be a carrier such as a wafer or an interlayer, where an integrated circuit is formed. The conductive pad 110, the passivation layer 120, and the seal ring 130 are formed in the fanout area of the wafer. In some embodiments, the conductive pad 110 may be made of conductive material, such as metal (e.g. aluminum), the passivation layer 120 may be made of dielectric material, and the seal ring 130 may be made of metal.

Subsequently, a dielectric layer 140 is formed over the substrate 100, the conductive pad 110, and the passivation layer 120. The dielectric layer 140 covers the passivation layer 120 and the conductive pad 110, exposes a second portion 110B of the first portion 110A of the conductive pad 110, and further exposes a portion of the passivation layer 120. In some embodiments, the dielectric layer 140 may be organic material, such as polyimide (PI) or polybenzoxazole (PBO).

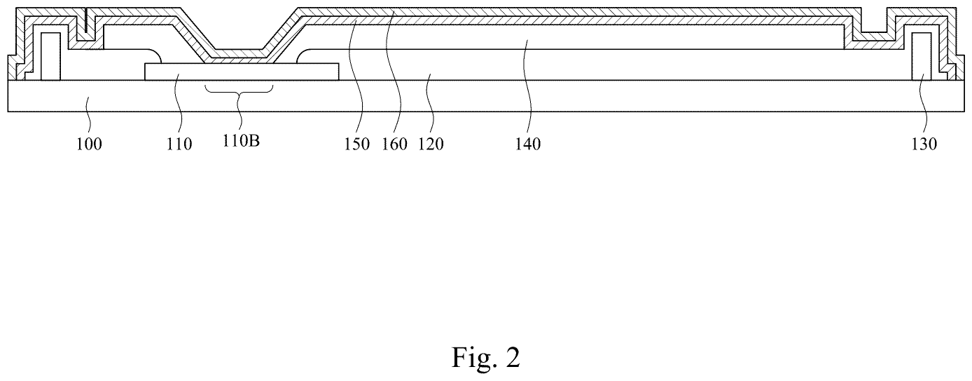

Referring to FIG. 2, a seed layer 150 is formed over the dielectric layer 140, and a seed layer 160 is formed over the seed layer 150. The seed layer 150 is in contact with the second portion 110B of the conductive pad 110. The seed layer 150 and the seed layer 160 are made of conductive material, such as metal. In some embodiments, the seed layer 150 and the seed layer 160 are made of different materials. For example, the seed layer 150 may be formed from a material that has better adhesion to the dielectric layer 140, such as titanium-tungsten (TiW). The seed layer 160 may be formed from a material that is more suitable for forming wirings, such as copper (Cu). In some embodiments, a thickness of the seed layer 150 ranges from, for example, 50 nm to 300 nm. A thickness of the seed layer 160 ranges from, for example, 100 nm to 600 nm.

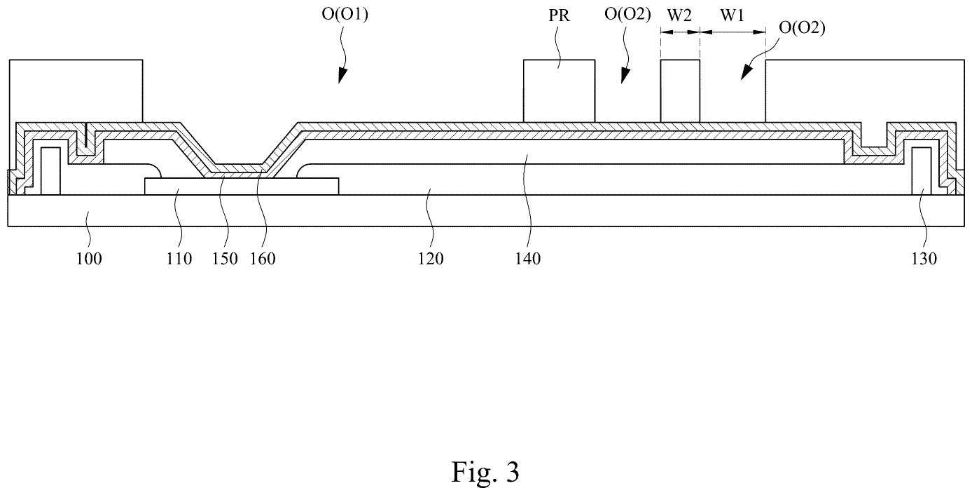

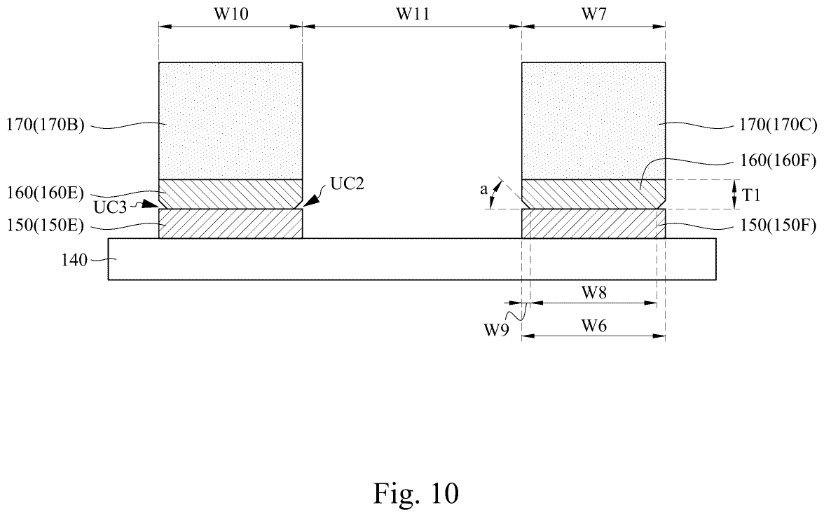

Referring to FIG. 3, a patterned photoresist layer PR is formed over the seed layer 160, and the patterned photoresist layer PR includes a plurality of openings O. Specifically, the openings O may include an opening O1 and a plurality of openings O2 (such as two openings O2). The width of the opening O1 is larger, and a portion of opening O1 overlaps with the conductive pad 110. The width of the openings O2 is smaller and does not overlap with the conductive pad 110. For example, the width of the opening O1 is larger than the width of the openings O2. The opening O1 is provided to electrically connect a subsequently formed routing layer with the underlying conductive pad 110, while the openings O2 are provided for forming a routing layer with a narrow line width. Each of the openings O2 has a width W1. The distance between the two openings O2 has a width W2, and the width W1 is greater than the width W2. The width W1 of the openings O2 is greater than the predetermined width of the routing layer (such as the respective width W10 of a second portion 170B and a third portion 170C of a routing layer 170 in FIG. 10). In some embodiments, the width W1 of the openings O2 may range from 2 μm to 8 μm. The width W2 between the two openings O2 may range from 1 μm to 8 μm. For example, if the predetermined width of the routing layer (such as the second portion 170B and the third portion 170C of the routing layer 170 in FIG. 10) is 2 μm, the width W1 may be 3.5 μm, and the width W2 may be 1 μm, however, the present disclosure is not limited thereto.

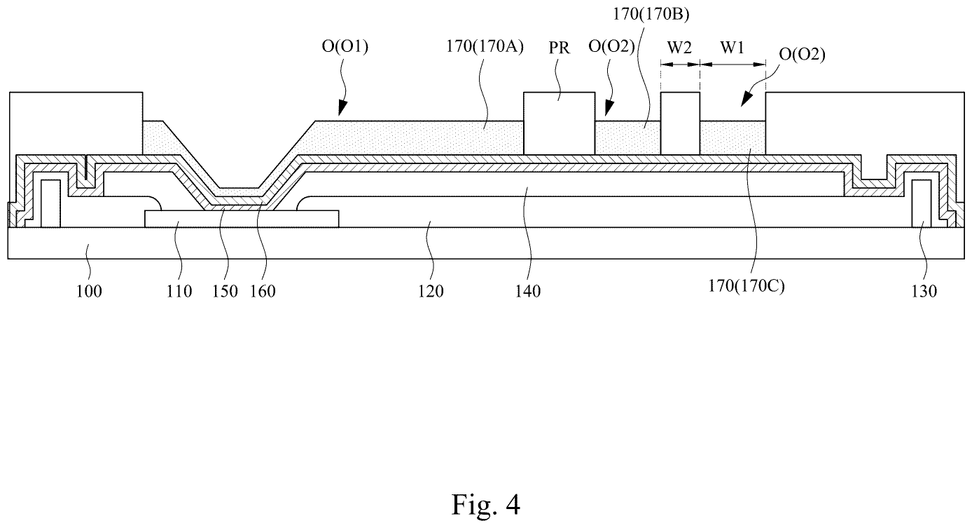

Referring to FIG. 4, the routing layer 170 is formed in the openings O over the seed layer 160. Specifically, the routing layer 170 may be formed in openings O by electroplating. The location of the routing layer 170 is restricted by the patterned photoresist layer PR, such that the routing layer 170 is divided into a first portion 170A, a second portion 170B, and a third portion 170C according to the patterned photoresist layer PR. The first portion 170A corresponds to the opening O1, and the second portion 170B and the third portion 170C corresponds to the two openings O2 respectively. The width between the second portion 170B and the third portion 170C of the routing layer 170 is the width W2 between the two openings O2. Therefore, the second portion 170B and the third portion 170C of the routing layer 170 have the width W1 respectively, the distance between the second portion 170B and the third portion 170C of the routing layer 170 has the width W2, and the width W1 is greater than the width W2. The first portion 170A of the routing layer 170 is electrically connected with the underlying conductive pad 110 through the seed layers 150 and 160. In some embodiments, at least two of the first portion 170A, the second portion 170B, and the third portion 170C of the routing layer 170 are connected in a top view (not illustrated). The routing layer 170 may be made of conductive material, such as metal. In some embodiments, the routing layer 170 and the seed layer 160 are made of the same material. For example, the routing layer 170 and the seed layer 160 are made of copper, and the routing layer 170 and the seed layer 150 are made of different materials.

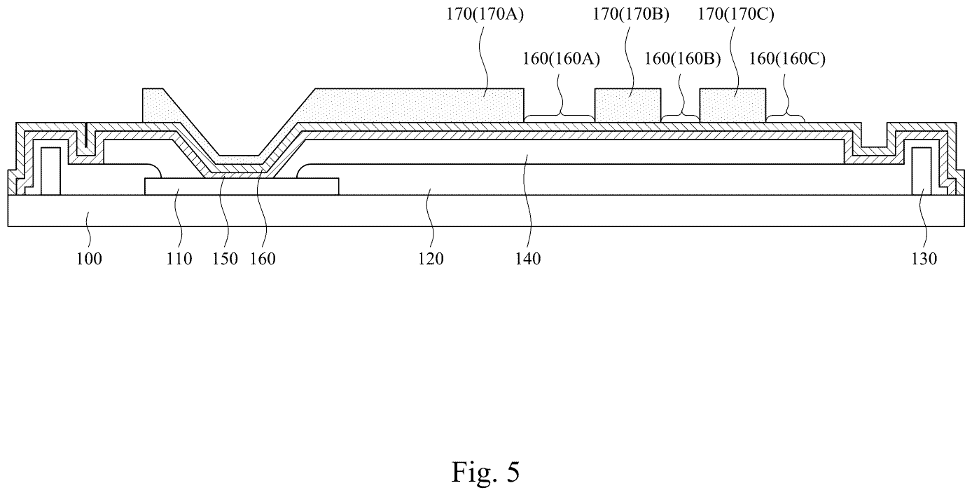

Subsequently, referring to FIG. 5, the patterned photoresist layer PR is removed. After the patterned photoresist layer PR is removed, the routing layer 170 remains over the seed layer 160. A first portion 160A, a second portion 160B, and a third portion 160C of the seed layer 160 are exposed according to the layout of the first portion 170A, the second portion 170B, and the third portion 170C of the routing layer 170. In some embodiments, the routing layer 170 may serve as a redistribution layer (RDL), however, the present disclosure is not limited thereto.

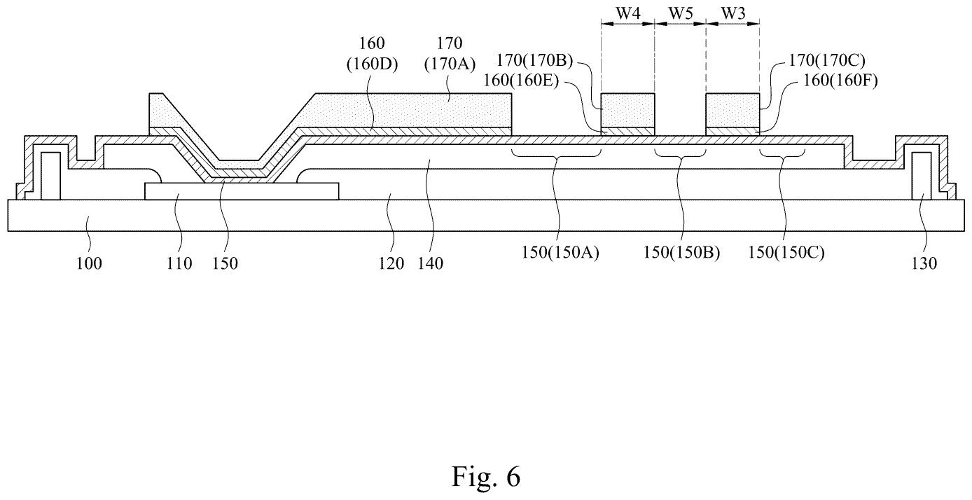

Referring to FIG. 6, the seed layer 160 is etched by using the routing layer 170 as a mask. Specifically, a first wet etching process is performed to remove the first portion 160A, the second portion 160B, and the third portion 160C of the seed layer 160 exposed by the routing layer 170. At this time, a fourth portion 160D, a fifth portion 160E, and a sixth portion 160F of the seed layer 160 remain in place. A first portion 150A, a second portion 150B, and a third portion 150C of the seed layer 150 are exposed according to the layout of the fourth portion 160D, the fifth portion 160E, and the sixth portion 160F of the seed layer 160. The fifth portion 160E and the sixth portion 160F of the seed layer 160 have a third width W3 after the etching. In some embodiments, the routing layer 170 and the seed layer 160 are made of the same material, such that the first wet etching process is performed by substantially the same etching rate for the routing layer 170 and the seed layer 160. The first wet etching process is further performed to reduce the width of the second portion 170B and the third portion 170C of the routing layer 170 from the width W1 to a width W4, and a width W5 between the second portion 170B and the third portion 170C of the routing layer 170 increases correspondingly compared to the width W2 (as shown in FIG. 4) that is present before the first wet etching process is performed. In some embodiments, the width W4 of the routing layer 170 is substantially the same as the width W3 of the seed layer 160. In some embodiments, the width W3 may range from 1 μm to 8μm, the width W4 may range from 1 μm to 8 μm, and the width W5 may range from 2 μm to 8 μm. For example, in the case where the width W1 is 3.5 μm and the width W2 is 1 μm, after the first wet etching process is performed, the width W3 and the width W4 may be 3 μm, and the width W5 may be 1.5 μm, however, the present disclosure is not limited thereto. In some embodiments, the etchant for the first wet etching process may be a mixture of phosphoric acid and hydrogen peroxide. In some embodiments, the duration of the first wet etching process may range from 5 seconds to 40 seconds.

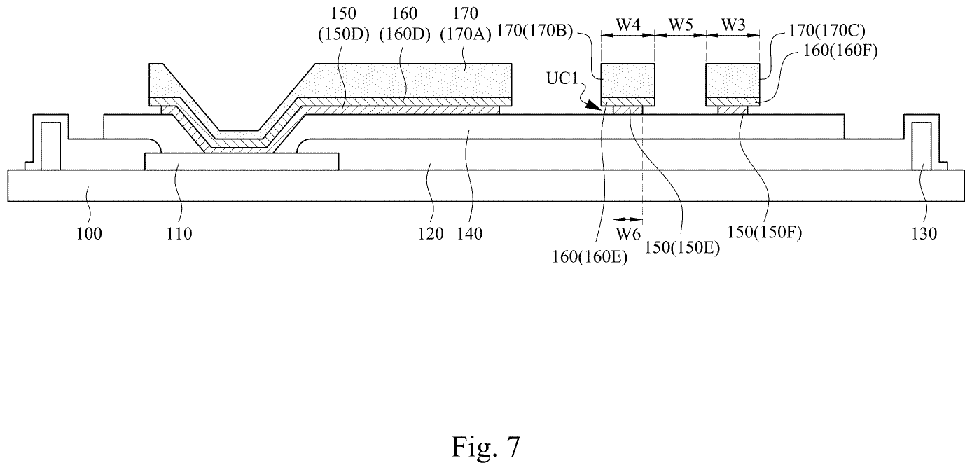

Referring to FIG. 7, the seed layer 150 is etched by using the seed layer 160 and the routing layer 170 as a mask. Specifically, a second wet etching process is performed to remove the first portion 150A, the second portion 150B, and the third portion 150C of the seed layer 150 exposed by the seed layer 160. At this time, a fourth portion 150D, a fifth portion 150E, and a sixth portion 150F of the seed layer 150 remain in place. Since the seed layer 150 and the seed layer 160 are made of different materials, the second etching process substantially does not etch the seed layer 160 during etching seed layer 150. Therefore, a width W6 of the seed layer 150 is less than the width W3 of the seed layer 160 due to the over-etching of the second wet etching process. That is, two opposite sidewalls (such as the left sidewall and the right sidewall) of the fourth portion 160D of the seed layer 160 are not aligned with the two opposite sidewalls (such as the left sidewall and the right sidewall) of the fourth portion 150D of the seed layer 150, two opposite sidewalls (such as the left sidewall and the right sidewall) of the fifth portion 160E of the seed layer 160 are not aligned with the two opposite sidewalls (such as the left sidewall and the right sidewall) of the fifth portion 150E of the seed layer 150, and two opposite sidewalls (such as the left sidewall and the right sidewall) of the sixth portion 160F of the seed layer 160 are not aligned with the two opposite sidewalls (such as the left sidewall and the right sidewall) of the sixth portion 150F of the seed layer 150. Therefore, after the second wet etching process, undercuts UC1 are formed on the surface of the dielectric layer 140 corresponding to locations of the fourth portion 150D, the fifth portion 150E, and the sixth portion 150F of the seed layer 150. In some embodiments, the width of each undercut UC1 (for example, a horizontal distance between the left sidewall of the fifth portion 150E of the seed layer 150 and the left sidewall of the fifth portion 160E of the seed layer 160) is 0.5 μm. When the undercuts UC1 are formed, the bonding strength between the interfaces where the undercuts UC1 are located will affect the structural strength. For example, when the bonding strength between the interfaces where the undercuts UC1 are located is weaker, the structure formed on the interfaces peel off easily. Since the undercuts UC1 are formed on the surface of the dielectric layer 140 and the bonding strength between the dielectric layer 140 and the seed layer 150 over the dielectric layer 140 is weak, it cause the seed layer 150, the seed layer 160, and the routing layer 170 to peel off easily. The peeling of the routing layer 170 may lead to an open circuit in the wiring. The bonding strength between the dielectric layer 140 and the seed layer 150 over the dielectric layer 140 is weaker because that the dielectric layer 140 and the seed layer 150 are made of materials with different properties. For example, one of the dielectric layer 140 and the seed layer 150 is an organic material, while the other thereof is a metallic material. In some embodiments, the etchant for the second wet etching process may be hydrogen peroxide. In some embodiments, the duration of the second wet etching process may range from 3 minutes to 20 minutes.

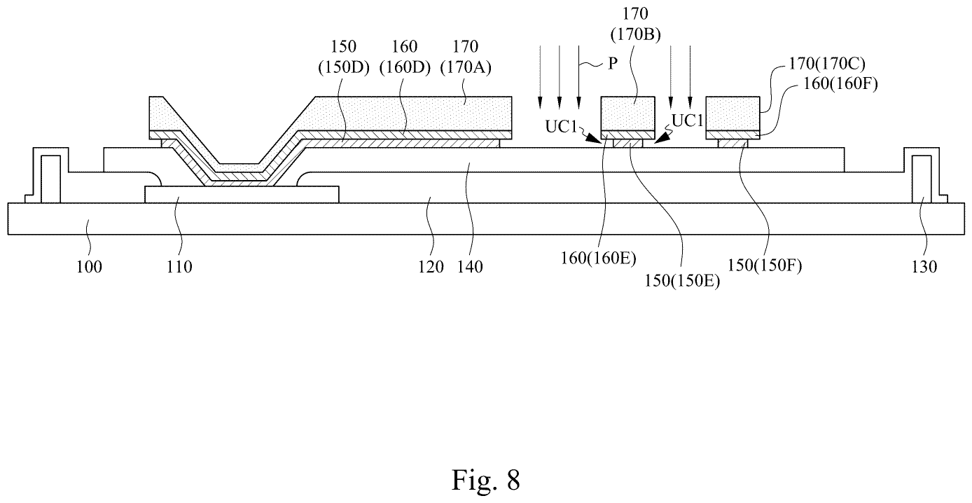

Referring to FIG. 8, after the seed layer 150 is etched, a plasma treatment P is performed to remove metal residues over the dielectric layer 140. The metal residues may be by-products caused by the etching to the seed layer 150, the seed layer 160, and the routing layer 170 as described previously. Removing the metal residues may reduce the possibility of current leakage of the routing layer 170.

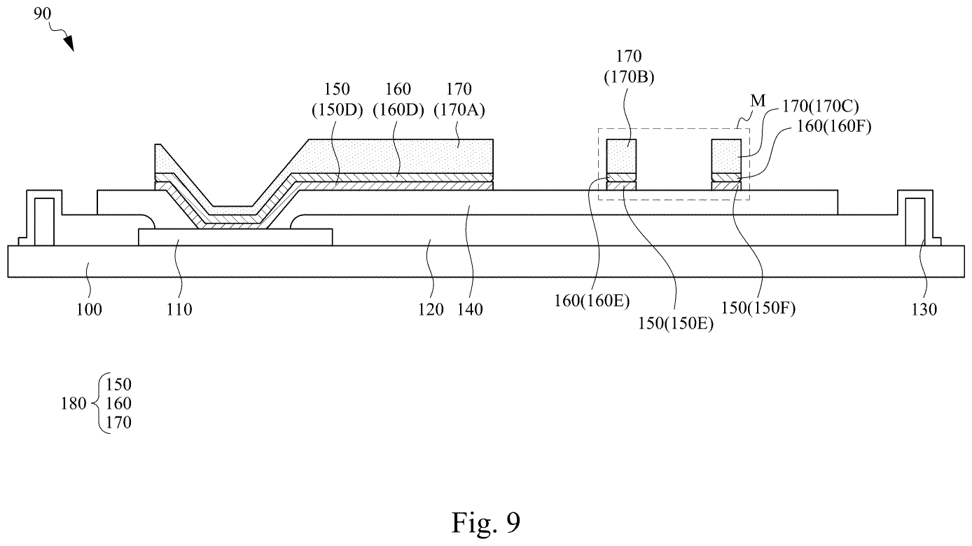

Referring to FIG. 9, the routing layer 170 and the seed layer 160 are etched again. Specifically, a third wet etching process is performed to reduce the width of the routing layer 170 and the seed layer 160. Specifically, FIG. 10 illustrates an enlargement view of the region M of FIG. 9. Referring to FIGS. 9 and 10, after the routing layer 170 and the seed layer 160 are etched again, the semiconductor device 90 includes the substrate 100, the conductive pad 110, the passivation layer 120, the seal ring 130, the dielectric layer 140, and a routing structure 180. The routing structure 180 includes the seed layer 150, the seed layer 160, and the routing layer 170. The dielectric layer 140 is over the conductive pad 110. The routing structure 180 penetrates the dielectric layer 140 and is electrically connected with the conductive pad 110. The seed layer 150 is over the dielectric layer 140. The seed layer 160 is over the seed layer 150, and undercuts UC2 are between the seed layer 150 and the seed layer 160. The routing layer 170 is over the seed layer 160. The “undercut U2” herein may be viewed as a recess formed between the seed layer 150 and the seed layer 160. For example, the fifth portion 160E of the seed layer 160 may have a substantially vertical right sidewall and an inclined sidewall extending downward from the substantially vertical sidewall, in which the undercut UC2 is defined by the inclined sidewall of the fifth portion 160E of the seed layer 160 and the top surface of the fifth portion 150E of the seed layer 150.

The third wet etching process is performed such that top portions of the fifth portion 160E and the sixth portion 160F of the seed layer 160 have a width W7 respectively, bottom portions of the fifth portion 160E and the sixth portion 160F of the seed layer 160 have a width W8 respectively, and the width W8 is less than the width W7. That is, the third wet etching process is performed to reduce the width of the tops of the fifth portion 160E and the sixth portion 160F of the seed layer 160 respectively from the width W3 to the width W7, and reduce the width of the bottom portions of the fifth portion 160E and the sixth portion 160F of the seed layer 160 respectively from the width W3 to the width W8. In some embodiments, the width W7 is substantially the same as the width W6. In some embodiments, the routing layer 170 and the seed layer 160 are made of the same material, so the third wet etching process is performed by substantially the same etching rate for the routing layer 170 and the fifth portion 160E and the sixth portion 160F of the seed layer 160. The third wet etching process is performed to further reduce the width of the second portion 170B and the third portion 170C of the routing layer 170 from the width W4 to the width W10. In some embodiments, the width W7 and the width W10 are substantially the same.

Since the materials of the seed layer 160 and the routing layer 170 are different from the material of the seed layer 150, the seed layer 150 is not substantially etched during the period when the third wet etching process is performed to etch the seed layer 160 and the routing layer 170, or the etching rate by which the third wet etching process is performed to etch the seed layer 160 and the routing layer 170 is greater than the etching rate by which the third wet etching process is performed to etch the seed layer 150. Therefore, the undercuts UC1 in FIG. 8 disappear because the width of the seed layer 160 and the routing layer 170 are reduced. Since the bottom corners of the seed layer 160 are more easily etched by the third wet etching process, the width W8 of the bottom portions of the fifth portion 160E and the sixth portion 160F of the seed layer 160 respectively is less than the width W7 of the top portions of the fifth portion 160E and the sixth portion 160F of the seed layer 160 respectively, and the undercuts UC2 are formed on the surfaces of the fifth portion 150E and the sixth portion 150F of the seed layer 150. When the routing layer 170 is subjected to external stress, the applied force concentrates at the undercuts UC2. The peeling occurs at the interface between the seed layer 150 and the seed layer 160. Furthermore, since the bonding strength between the seed layer 150 and the seed layer 160 is stronger than that between the seed layer 150 and the dielectric layer 140, the routing structure 180 becomes less prone to peeling, thereby reducing the risk of open-circuit issues. In some embodiments, the angle a of at least one of the undercuts UC2 is less than 60 degrees. In some embodiments, the angle a of at least one of the undercuts UC2 is greater than 15 degrees. The “angle a” herein may be the angle between one inclined sidewall of the seed layer 160 and the top surface of the seed layer 150. In some embodiments, a ratio of a width W9 of at least one of the undercuts UC2 to a thickness T1 of the seed layer 160 ranges from 0.6 to 1.8. For example, when the thickness T1 of the seed layer 160 is 0.3 μm, the width W9 of at least one of the undercuts UC2 ranges from 0.18 μm to 0.54 μm. In some embodiments, an undercut UC3 is further between the fifth portion 150E of the seed layer 150 and the fifth portion 160E of the seed layer 160, and the undercut UC2 and the undercut UC3 are located on opposite sides of the fifth portion 160E of the seed layer 160. Another undercut UC3 is further between the sixth portion 150F of the seed layer 150 and the sixth portion 160F of the seed layer 160, and the undercut UC2 and the undercut UC3 are located on opposite sides of the sixth portion 160F of the seed layer 160.

Moreover, since the third wet etching process is performed to further reduce the line width of the routing layer 170, the formed routing layer 170 may have a narrower line width, thereby increasing the routing space. For example, in some embodiments, after the third wet etching process is performed, the width W7 of the top portions of the fifth portion 160E and the sixth portion 160F of the seed layer 160 and the width W10 of the second portion 170B and the third portion 170C of the routing layer 170 may ranges from 1 μm to 8 μm, and the width W11 of the distance between the second portion 170B and the third portion 170C of the routing layer 170 may ranges from 2 μm to 8 μm. As a result, the size of the chip may be reduced, and no additional routing layers are required. In some embodiments, the etchant for the third wet etching process may be a mixture of phosphoric acid and hydrogen peroxide. In some embodiments, the duration of the third wet etching process may less than 5 seconds.

It is to be understood, however, that even though numerous characteristics and advantages of the present invention have been set forth in the foregoing description, together with details of the structure and function of the invention, and changes may be made in detail, especially in matters of shape, size, and arrangement of parts within the principles of the invention to the full extent indicated by the broad general meaning of the terms in which the appended claims are expressed.

What is claimed is:

1. A method of forming a semiconductor device, comprising:
forming a first seed layer over a dielectric layer;
forming a second seed layer over the first seed layer;
forming a routing layer over the second seed layer;
etching the second seed layer by using the routing layer as a first mask;
etching the first seed layer by using the second seed layer as a second mask; and
after etching the first seed layer, etching the routing layer and the second seed layer, wherein after etching the routing layer and the second seed layer, an undercut is formed between the first seed layer and the second seed layer.

2. The method of claim 1, wherein after etching the routing layer and the second seed layer, a width of a top portion of the second seed layer is the same as a width of the first seed layer.

3. The method of claim 1, wherein forming the routing layer over the second seed layer comprises:
forming a patterned photoresist layer over the second seed layer, wherein the patterned photoresist layer comprises a plurality of openings; and
forming the routing layer in the plurality of openings.

4. The method of claim 3, wherein the plurality of openings have a first width, a distance between the plurality of openings has a second width, and the first width is greater than the second width.

5. The method of claim 1, wherein etching the second seed layer by using the routing layer as the first mask comprises:
performing a first wet etching process to remove the second seed layer exposed by the routing layer, the second seed layer being etched has a first width.

6. The method of claim 5, wherein the first wet etching process is performed by substantially the same etching rate for the routing layer and the second seed layer.

7. The method of claim 5, wherein the first wet etching process is further performed to reduce the routing layer from a second width to a third width.

8. The method of claim 7, wherein etching the first seed layer by using the second seed layer as the second mask comprises:
performing a second wet etching process, such that a fourth width of the first seed layer is less than the first width of the second seed layer.

9. The method of claim 8, wherein after etching the first seed layer, etching the routing layer and the second seed layer comprises:
performing a third wet etching process, such that a top portion of the second seed layer has a fifth width, a bottom portion of the second seed layer has a sixth width less than the fifth width.

10. The method of claim 9, wherein the third wet etching process is further performed to reduce the routing layer from the third width to a seventh width.

11. The method of claim 9, wherein the third wet etching process is performed by substantially the same etching rate for the routing layer and the second seed layer.

12. The method of claim 9, wherein an etching rate by which the third wet etching process is performed to etch the second seed layer is greater than an etching rate by which the third wet etching process is performed to etch the first seed layer.

13. The method of claim 1, further comprising:
after etching the first seed layer, performing a plasma treatment to remove metal residues over the dielectric layer.

14. The method of claim 1, wherein the routing layer and the second seed layer are made of the same material.

15. A semiconductor device, comprising:
a conductive pad;
a dielectric layer over the conductive pad; and
a routing structure penetrating the dielectric layer and electrically connected with the conductive pad, the routing structure comprising:
a first seed layer over the dielectric layer;
a second seed layer over the first seed layer, wherein a width of a top portion of the second seed layer is substantially the same as a width of the first seed layer, and a first undercut is between the first seed layer and the second seed layer; and
a routing layer over the second seed layer.

16. The semiconductor device of claim 15, wherein an angle of the first undercut is less than 60 degrees.

17. The semiconductor device of claim 15, wherein a ratio of a width of the first undercut to a thickness of the second seed layer ranges from 0.6 to 1.8.

18. The semiconductor device of claim 15, wherein a second undercut is between the first seed layer and the second seed layer, and the first undercut and the second undercut are located on opposite sides of the second seed layer.

19. The semiconductor device of claim 15, wherein the first undercut is defined by an inclined sidewall of the second seed layer and a top surface of the first seed layer.

20. The semiconductor device of claim 15, wherein the width of the top portion of the second seed layer is greater than a width of a bottom portion of the second seed layer.
